(19) United States
(12) Patent Application Publication
(10) Pub. No.: US 2026/0212948 A1
(43) Pub. Date: Jul. 23, 2026

(54) STORAGE DEVICE, TEST SYSTEM FOR SUDDEN POWER-OFF RECOVERY, AND OPERATING METHOD THEREOF

(71) Applicant: Samsung Electronics Co., Ltd., Suwon-si (KR)

(72) Inventors: Sunghee Lee, Suwon-si (KR); Dae Won Kim, Suwon-si (KR)

(21) Appl. No.: 19/450,298

(22) Filed: Jan. 15, 2026

(30) Foreign Application Priority Data
Jan. 21, 2025 (KR) 10-2025-0009049

(51) Int. Cl. G11C 29/50

(52) U.S. Cl. CPC G11C 29/50004; G11C 2029/5006

(57) ABSTRACT

A test system includes: a power supply device that supplies a power to a storage device including a plurality of nonvolatile memories; a current measurement device that measures a current consumed by the storage device; and a host device that controls the power supply device to cut off the power when the storage device is performing a target operation. The host device stores a plurality of current profiles respectively corresponding to a plurality of operations of the storage device, and identifies whether the storage device is performing the target operation, based on the current measured through the current measurement device and the plurality of current profiles.

### CROSS-REFERENCE TO RELATED APPLICATIONS

This application claims priority under 35 U.S.C. § 119 to Korean Patent Application No. 10-2025-0009049 filed on January 21, 2025, in the Korean Intellectual Property Office, the disclosures of which are incorporated by reference herein in their entireties.

### BACKGROUND

In some examples, storage devices may be expected to maintain data consistency even under unpredictable operating conditions. Evaluating behavior of storage devices during such events may be desired for ensuring system reliability and data integrity.

### SUMMARY

In some cases, an unexpected sudden power failure (hereinafter, referred to as “sudden power-off (SPO)”) may occur. In such cases, a storage device processes data in compliance with a predefined policy according to data consistency.

A sudden power-off recovery (SPOR) test is a test to determine whether the storage device processes data in compliance with the policy in an SPO event. Generally, the SPOR test may be performed in a state of randomly blocking an operation of the storage device regardless of a type of an operation which the storage device is performing or whether the nonvolatile memory included in the storage device is performing a storage operation.

In such cases, because the target of the SPOR test (i.e., the extent of data damaged by the SPO) may be incapable of being clearly specified, it may be difficult to determine a test coverage. Accordingly, a test time may be lengthened, and the efficiency of the test may be reduced.

Implementations of the present disclosure provide a test system capable of performing a sudden power-off recovery (SPOR) test more efficiently.

In some aspects, the present disclosure provides a test system that includes a power supply device that supplies a power to a storage device including a plurality of nonvolatile memories, a current measurement device that measures a current consumed by the storage device, and a host device that controls the power supply device to cut off the power when the storage device is performing a target operation. The host device may store a plurality of current profiles respectively corresponding to a plurality of operations of the storage device, and may identify whether the storage device is performing the target operation, based on the current measured through the current measurement device and the plurality of current profiles.

In some implementations, when the current measured through the current measurement device corresponds to a current profile associated with the target operation from among the plurality of current profiles, the host device may identify that the storage device is performing the target operation.

In some implementations, each of the plurality of current profiles may include at least one of a waveform or a representative value of a current consumed by the storage device during the corresponding operation.

In some implementations, the host device may control the power supply device to cut off the power while a target nonvolatile memory among the plurality of nonvolatile memories is operating depending on the target operation.

In some implementations, whether the target nonvolatile memory is operating may be identified based on a busy signal output from the target nonvolatile memory, and the busy signal may have one of a first voltage corresponding to a state where the target nonvolatile memory is operating or a second voltage corresponding to a state where an operation of the target nonvolatile memory is completed.

In some implementations, the host device may transmit, to the storage device, a selection signal for selecting a busy signal output from the target nonvolatile memory from among busy signals respectively output from the plurality of nonvolatile memories.

In some implementations, the busy signal output from the target nonvolatile memory may be received by the host device, and when the current measured through the current measurement device corresponds to a current profile associated with the target operation from among the plurality of current profiles and the received busy signal has the first voltage, the host device may control the power supply device to cut off the power.

In some implementations, the busy signal output from the target nonvolatile memory may be received by the power supply device, the host device may transmit information about a cut-off time point of the power to the power supply device, based on that the current measured through the current measurement device corresponds to a current profile associated with the target operation from among the plurality of current profiles, and the power supply device may identify whether the cut-off time point of the power arrives, based on the received busy signal, and may cut off the power at the identified time point.

In some implementations, the plurality of operations of the storage device may be test operations implemented through a combination of commands defined by a protocol used for communication between the host device and the storage device, and the protocol may include non-volatile memory express (NVMe), universal flash storage (UFS), small computer system interface (SCSI), serial attached SCSI (SAS), or serial ATA (SATA).

In some implementations, the host device may control the storage device to perform each of the plurality of operations, and may obtain a current profile corresponding to each of the plurality of operations based on a current measured through the current measurement device while the storage device is performing each of the plurality of operations.

In some implementations, the host device may control the power supply device to again supply the power to the storage device, after the power being supplied to the storage device is cut off and may check, from the storage device, a result of an operation of the storage device performed as the power is cut off during the target operation.

In some implementations, the power supply device may include a power management integrated circuit (PMIC) for managing a power to be supplied, and the current measurement device may be implemented by using the power management integrated circuit of the power supply device.

In some implementations, the storage device may include a power management integrated circuit (PMIC) for managing a power used within the storage device, and the current measurement device may be implemented by using the power management integrated circuit of the storage device.

In some aspects, the present disclosure provides a storage device including a plurality of nonvolatile memories, each of which includes a busy signal through which a busy signal is output, a controller that controls operations of the plurality of nonvolatile memories, and a multiplexer that is connected to busy pins of the plurality of nonvolatile memories and outputs a busy signal of a nonvolatile memory selected from the plurality of nonvolatile memories to the outside.

In some implementations, in response to that a selection signal for selecting a target nonvolatile memory among the plurality of nonvolatile memories is received, the controller may control the multiplexer to output a busy signal corresponding to the target nonvolatile memory from among the busy signals of the plurality of nonvolatile memories.

In some implementations, the storage device may further include a power management integrated circuit for managing a power used within the storage device, and the controller may obtain information about a current consumed while the storage device is operating, by using the power management integrated circuit, and may transmit the obtained information of the current to the outside through a side band interface.

In some aspects, the present disclosure provides an operating method of a test system. The operating method includes supplying a power to a storage device including a plurality of nonvolatile memories, measuring a current consumed by the storage device, identifying whether the storage device is performing a target operation, based on the measured current and a plurality of current profiles, and cutting off a power being supplied to the storage device based on that the storage device is performing the target operation, and the plurality of current profiles may correspond to a plurality of operations of the storage device, respectively.

In some implementations, the cutting-off of the power may include cutting off the power while a target nonvolatile memory among the plurality of nonvolatile memories is operating depending on the target operation.

In some implementations, whether the target nonvolatile memory is operating may be identified based on a busy signal from the target nonvolatile memory, and the busy signal of the target nonvolatile memory may have one of a first voltage corresponding to a state where the target nonvolatile memory is operating or a second voltage corresponding to a state where an operation of the target nonvolatile memory is completed.

In some implementations, the method may further include transmitting, to the storage device, a selection signal for selecting a busy signal corresponding to the target nonvolatile memory from among busy signals of the plurality of nonvolatile memories, and the busy signal of the target nonvolatile memory is output from the storage device based on the selection signal.

### BRIEF DESCRIPTION OF THE DRAWINGS

FIG. 1 is a block diagram of an example of a test system.

FIG. 2 is a diagram for describing an example of a method of obtaining current profiles.

FIG. 3 is a flowchart illustrating an example of an operating method of a test system.

FIG. 4 is a block diagram of an example of a test system.

FIG. 5 is a flowchart describing an example of an operating method of an example test system.

FIG. 6 is a block diagram of an example of a test system.

FIG. 7 is a block diagram of an example of a test system.

FIG. 8 is a block diagram of an example of a test system.

FIG. 9 is a block diagram of an example of a test system.

FIG. 10 is a flowchart describing an example of an operating method of an example test system.

### DETAILED DESCRIPTION

Below, implementations of the present disclosure will be described in detail and clearly to such an extent that an ordinary one in the art easily carries out the present disclosure.

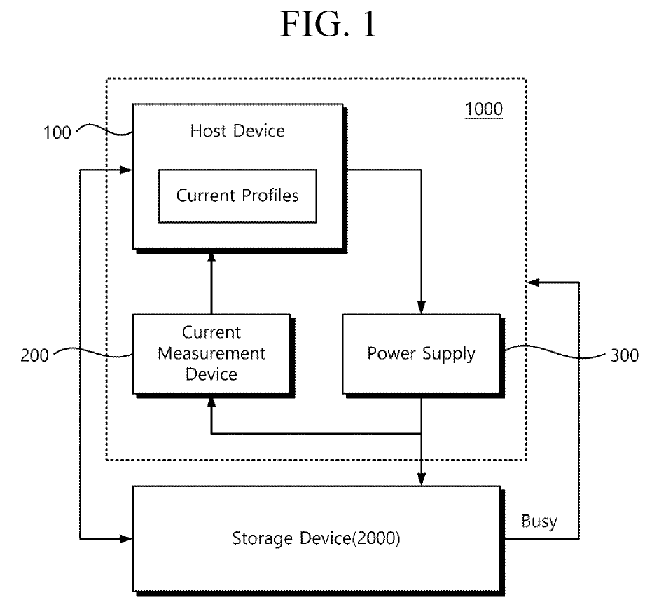

FIG. 1 is a block diagram of a test system according to some implementations of the present disclosure.

A test system 1000 according to some implementations of the present disclosure may perform a sudden power-off recovery (hereinafter, referred to as “SPOR”) test on a storage device 2000. In the SPOR test, the test system 1000 may cut off a power being supplied to the storage device 2000 while the storage device 2000 is operating.

In this case, according to some implementations, when the storage device 2000 performs a specific operation (hereinafter, referred to as a “target operation”), the test system 1000 may cut off the power being supplied to the storage device 2000. To this end, the test system 1000 may identify an operation (or a kind of an operation), which the storage device 2000 is currently performing, based on a current which the storage device 2000 consumes during an operation.

Also, according to some implementations, the test system 1000 may cut off the power being supplied to the storage device 2000 while a specific nonvolatile memory (hereinafter, referred to as a “target nonvolatile memory”) among the plurality of nonvolatile memories included in the storage device 2000 is performing an operation depending on the target operation. To this end, the test system 1000 may identify whether the target nonvolatile memory is currently operating, based on a busy signal (or a ready/busy signal) provided from the storage device 2000.

That is, according to some implementations of the present disclosure, the test system 1000 may specify the operation of the storage device 2000 to perform the SPOR test. Also, the test system 1000 may specify a nonvolatile memory included in the storage device 2000 to perform the SPOR test. In this case, the target of the SPOR test (i.e., the extent of data damaged by the SPO) may be clearly specified, and the coverage of the performed SPOR test may be clearly determined. According to the above description, an SPOR test time may be shortened, that is, the SPOR test may be performed more efficiently.

The description will be given in detail with reference to FIG. 1. Referring to FIG. 1, the test system 1000 may include a host device 100, a current measurement device 200, and a power supply device 300.

The power supply device 300 may control a power which is supplied to the storage device 2000. For example, under control of the host device 100, the power supply device 300 may supply the power to the storage device 2000 or may cut off the power being supplied to the storage device 2000. To this end, the power supply device 300 may be connected to a power pin of the storage device 2000.

The current measurement device 200 may measure a current which is consumed by the storage device 2000 while the storage device 2000 is operating. In some examples, the current measurement device 200 may be connected to the power pin of the storage device 2000. In some examples, the current measurement device 200 may provide information about the measured current (hereinafter, referred to as a “current profile”) to the host device 100. In this case, the current profile may include at least one of a waveform of the measured current over time or a representative value of the measured current. Herein, the representative value may include an average value, a center value, or a root mean square (RMS) value.

The host device 100 may control all operations of the test system 1000. The host device 100 may be implemented with various kinds of computing devices which perform a host function on the storage device 2000.

In particular, the host device 100 may perform the SPOR test on the storage device 2000. To this end, the host device 100 may control the operation of the storage device 2000. The host device 100 and the storage device 2000 may communicate with each other by using a protocol such as non-volatile memory express (NVMe), universal flash storage (UFS), small computer system interface (SCSI), serial attached SCSI (SAS), or serial ATA (SATA). Also, the host device 100 may control operations of the current measurement device 200 and the power supply device 300. In some examples, the host device 100 may communicate with the current measurement device 200 and the power supply device 300 by using an inter-integrated circuit (I2C) protocol.

For example, when the storage device 2000 is performing the target operation, the host device 100 may control the power supply device 300 to cut off the power being supplied to the storage device 2000.

To this end, the host device 100 may store a plurality of current profiles respectively corresponding to a plurality of operations of the storage device 2000. Herein, the plurality of operations of the storage device 2000 may be a plurality of test operations implemented through a combination of commands defined by the protocol used for the communication between the host device 100 and the storage device 2000. Also, each of the plurality of current profiles may include at least one of a waveform or a representative value of a current consumed by the storage device 2000 during the corresponding operation.

According to the above description, the host device 100 may identify whether the storage device 2000 is performing the target operation, based on the current measured by the current measurement device 200 and the plurality of current profiles. In detail, when the current measured by the current measurement device 200 corresponds to a current profile associated with the target operation from among the plurality of current profiles, the host device 100 may identify that the storage device 2000 is performing the target operation.

Also, while the target nonvolatile memory included in the storage device 2000 is operating depending on the target operation, the host device 100 may control the power supply device 300 to cut off the power being supplied to the storage device 2000.

In this case, whether the target nonvolatile memory operates may be identified based on the busy signal (hereinafter, referred to as a “target busy signal”) output from the target nonvolatile memory. The busy signal may have one of a first voltage corresponding to a state where a nonvolatile memory is operating or a second voltage corresponding to a state where the operation of the nonvolatile memory is completed. Accordingly, when the target busy signal has the first voltage, the target nonvolatile memory may be identified as operating.

According to some implementations, the target busy signal may be transferred to the host device 100 or may be transferred to the power supply device 300.

When the target busy signal is transferred to the host device 100, the host device 100 may identify whether the target nonvolatile memory is operating, based on the target busy signal. When it is identified that the target nonvolatile memory is operating, the host device 100 may control the power supply device 300 to cut off the power being supplied to the storage device 2000.

In this case, a time point at which the host device 100 controls the power supply device 300 such that the power being supplied to the storage device 2000 is cut off may be selected by the host device 100. For example, while the target operation is being performed, in some cases, the target nonvolatile memory may operate multiple times, not only once. That is, the target busy signal may have a plurality of transitions between the first voltage and the second voltage while the storage device 2000 is performing the target operation. Accordingly, the host device 100 may select a time point at which the power being supplied to the storage device 2000 is cut off, by selecting one of a plurality of time points at which the target busy signal has the first voltage and controlling the power supply device 300 at the selected time point.

Meanwhile, when the target busy signal is transferred to the power supply device 300, the power supply device 300 may identify whether the target nonvolatile memory is operating, based on the target busy signal. In this case, the host device 100 may in advance transmit information about the power cut-off time point to the power supply device 300, and thus, there may be cut off the power being supplied to the storage device 2000 while the target nonvolatile memory is operating.

In this case, the information about the power cut-off time point may include information about one time point selected by the host device 100 from among the plurality of time points at which the target busy signal has the first voltage. Accordingly, for example, when a third time point at which the target busy signal has the first voltage is selected at the power cut-off time point, the power supply device 300 may identify the corresponding time point based on the target busy signal and may cut off the power being supplied to the storage device 2000 at the corresponding time point.

Meanwhile, according to some implementations, the host device 100 may transmit, to the storage device 2000, a selection signal for selecting a target busy signal among busy signals respectively output from the plurality of nonvolatile memories included in the storage device 2000. According to the above description, the storage device 2000 may provide the test system 1000 with the target busy signal among the busy signals respectively output from the plurality of nonvolatile memories. This will be described in detail later.

According to the above implementations of the present disclosure, a test system capable of performing the SPOR test more efficiently may be provided.

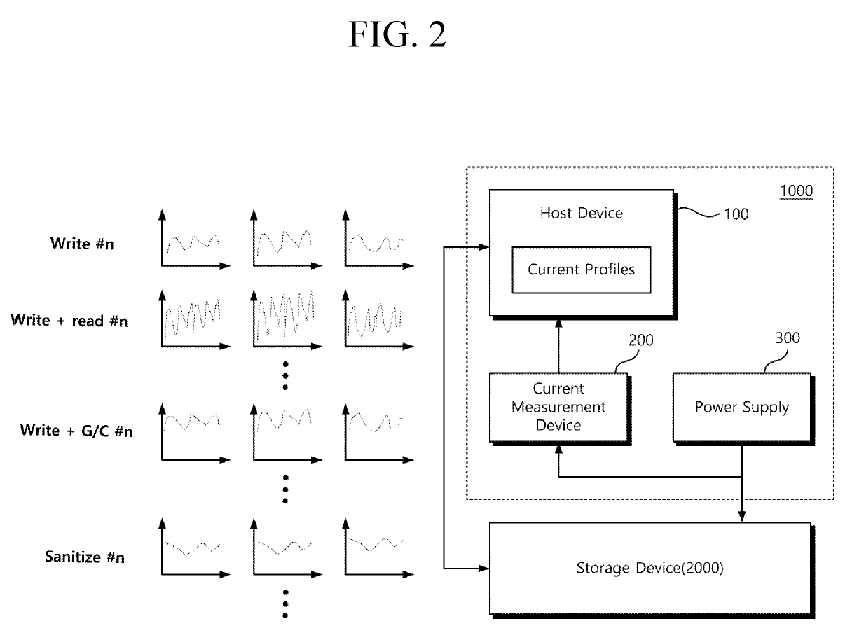

FIG. 2 is a diagram for describing a method of obtaining current profiles, according to some implementations of the present disclosure.

The host device 100 may obtain a plurality of current profiles respectively corresponding to a plurality of operations of the storage device 2000. In this case, the plurality of operations of the storage device 2000 may include a plurality of test operations implemented through a combination of commands defined in the protocol specification such as non-volatile memory express (NVMe), universal flash storage (UFS), small computer system interface (SCSI), serial attached SCSI (SAS), or serial ATA (SATA).

Referring to FIG. 2, the plurality of operations may include combinations of write commands, combinations of a write command and a read command, combinations of a write command and a garbage collection operation, combinations of a sanitize operation, etc. In this case, each combination may be variously provided by differently setting the capacity of data associated with the corresponding command or the number of times of the corresponding command. For example, the combinations of write commands may be variously provided by differently setting the capacity of data to be written in the storage device 2000 or the number of continuous write operations. The above description is also applied to the remaining combinations.

According to some implementations, the host device 100 may control the storage device 2000 to perform the plurality of operations, respectively and may obtain a current profile corresponding to each operation based on a current measured through the current measurement device 200 while the storage device 2000 is performing each operation. In this case, the current profile may include at least one of a waveform or a representative value of a current consumed by the storage device 2000 during each operation. The current profiles obtained in association with the operations of the storage device 2000 may be stored in the host device 100.

Meanwhile, as understood from graphs illustrated in FIG. 2, the current profiles associated with the plurality of operations of the storage device 2000 may differ for each operation. Accordingly, when the host device 100 performs the SPOR test, the host device 100 may identify whether the storage device 2000 is performing the target operation, based on the plurality of current profiles thus stored, and when the storage device 2000 performs the target operation, the host device 100 may cut off the power being supplied to the storage device 2000.

In detail, when the host device 100 performs the SPOR test, the host device 100 may control the storage device 2000 to perform at least one test operation including the target operation. In this case, the current measurement device 200 may measure a current consumed by the storage device 2000 and may provide a current profile to the host device 100. According to the above description, the host device 100 may identify whether the target operation is being performed, based on that the current profile provided from the current measurement device 200 corresponds to a current profile associated with the target operation from among the stored current profiles. Accordingly, when the storage device 2000 is performing the target operation, the host device 100 may control the power supply device 300 to cut off the power being supplied to the storage device 2000.

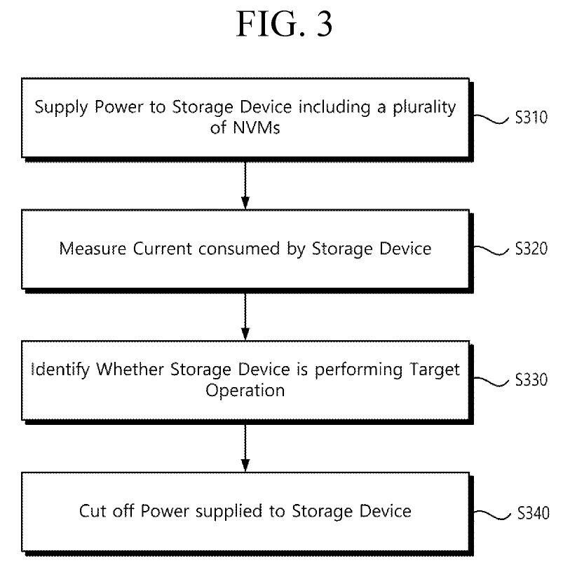

FIG. 3 is a flowchart illustrating an operating method of a test system according to some implementations of the present disclosure. An operating method of a test system to be described with reference to FIG. 3 may correspond to the operating method of the test system 1000 described with reference to FIG. 1.

Referring to FIG. 3, in operation S310, the test system 1000 may supply the power to the storage device 2000 including a plurality of nonvolatile memories. For example, the host device 100 may control the power supply device 300 to supply the power to the storage device 2000.

In operation S320, the test system 1000 may measure a current consumed by the storage device 2000. For example, when the power is supplied to the storage device 2000, the storage device 2000 may perform a predefined operation even though a command corresponding to a separate test operation is not applied from the host device 100. Also, when commands corresponding to a plurality of operations are received from the host device 100 depending on a test scenario, the storage device 2000 may perform the operations corresponding to the received commands. In this case, the current measurement device 200 may measure a current consumed by the storage device 2000 from a time point at which the power is supplied to the storage device 2000 and may provide the host device 100 with a current profile varying over time.

In operation S330, the test system 1000 may identify whether the storage device 2000 is performing the target operation, based on the measured current and the plurality of current profiles. In detail, the host device 100 may store the plurality of current profiles respectively corresponding to the plurality of operations of the storage device 2000. Accordingly, for example, when a current profile similar to a current profile corresponding to the target operation from among the stored current profiles is provided from the current measurement device 200, the host device 100 may identify that the storage device 2000 is performing the target operation.

In operation S340, the test system 1000 may cut off the power being supplied to the storage device 2000 based on that the storage device 2000 is performing the target operation. According to some implementations, while a target nonvolatile memory among the plurality of nonvolatile memories is operating depending on the target operation of the storage device 2000, the test system 1000 may cut off the power being supplied to the storage device 2000. In this case, whether the target nonvolatile memory is operating may be identified based on the busy signal of the target nonvolatile memory.

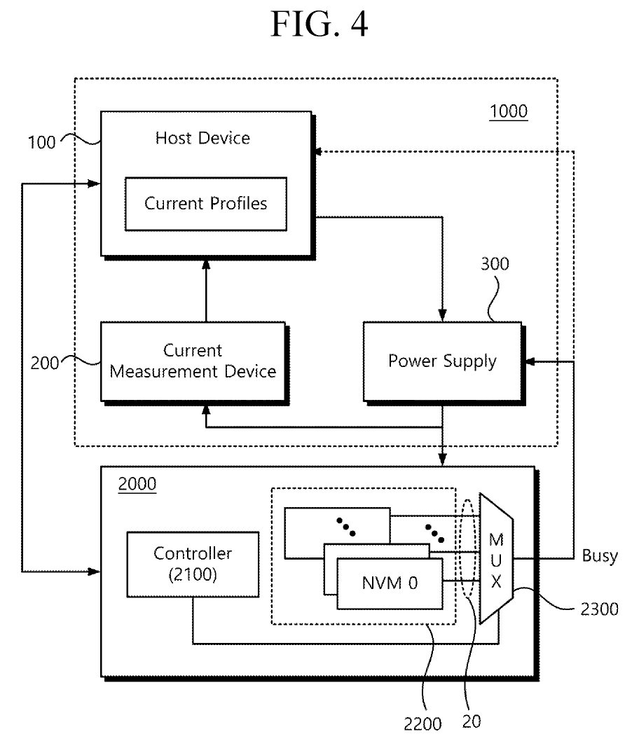

FIG. 4 is a block diagram of a test system according to some implementations of the present disclosure. The test system 1000 and the storage device 2000 of FIG. 4 may respectively correspond to the test system 1000 and the storage device 2000 of FIG. 1. In FIG. 4, the description associated with components the same as the above components will be omitted or simplified.

As described above, the storage device 2000 may provide the target busy signal to the test system 1000. To this end, the host device 100 may transmit, to the storage device 2000, the selection signal for selecting a target busy signal among busy signals 20 respectively output from the plurality of nonvolatile memories included in the storage device 2000. According to the above description, the storage device 2000 may provide the test system 1000 with the target busy signal among the busy signals 20.

In detail, referring to FIG. 4, the storage device 2000 may include a plurality of nonvolatile memories 2200, a controller 2100, and a multiplexer 2300.

For example, the plurality of nonvolatile memories 2200 may be NAND flash memory chips. According to some implementations, the plurality of nonvolatile memories 2200 may be vertical NAND (VNAND) flash memory chips. The vertical NAND flash memory chip may include word lines stacked on a substrate in a vertical direction and cell strings each including a plurality of memory cells respectively connected to the word lines. In some implementations, the plurality of nonvolatile memories 2200 may be NOR flash memory chips.

The plurality of nonvolatile memories 2200 may receive a command and an address from the controller 2100 through at least one channel and may exchange data with the controller 2100.

Each of the plurality of nonvolatile memories 2200 may include a busy pin through which the busy signal 20 is output. In this case, the busy signal may have one of the first voltage corresponding to a state where a corresponding nonvolatile memory is operating or the second voltage corresponding to a state where the operation of the corresponding nonvolatile memory is completed.

The multiplexer 2300 may be connected to the busy pins of the plurality of nonvolatile memories 2200 and may output a busy signal of one nonvolatile memory, which is selected under control of the controller 2100, from among the plurality of nonvolatile memories 2200 to the outside.

The controller 2100 may control operations of the plurality of nonvolatile memories 2200 through at least one channel. For example, the controller 2100 may write data in the plurality of nonvolatile memories 2200 depending on a request of the host device 100. Also, the controller 2100 may read or erase the data stored in the plurality of nonvolatile memories 2200 depending on a request of the host device 100. In addition, the controller 2100 may perform an operation, such as a garbage collection (G/C) operation or a wear-leveling operation, on the plurality of nonvolatile memories 2200.

In response to that the selection signal for selecting the target nonvolatile memory among the plurality of nonvolatile memories 2200 is received from the host device 100, the controller 2100 may control the multiplexer 2300 to output the target busy signal among the busy signals 20 of the plurality of nonvolatile memories 2200. According to the above description, the storage device 2000 may provide the target busy signal to the test system 1000.

According to some implementations, as illustrated by a dotted-line arrow of FIG. 4, the target busy signal may be transferred to the host device 100. In this case, when the target nonvolatile memory is operating while the storage device 2000 is performing the target operation, the host device 100 may cut off the power of the storage device 2000.

For example, when a current measured through the current measurement device 200 corresponds to a current profile associated with the target operation from among the plurality of current profiles and the received target busy signal has the first voltage, the host device 100 may apply a control signal to the power supply device 300 to cut off the power being supplied to the storage device 2000.

In this case, as described above, a time point at which the control signal for cutting off the power is applied to the power supply device 300 may be determined by the host device 100. For example, the host device 100 may select one of multiple time points at which a target nonvolatile memory is operating depending on the target operation and may apply the control signal for cutting off the power being supplied to the power supply device 300 to the storage device 2000 at the selected time point.

Also, according to some implementations, as illustrated by a solid-line arrow of FIG. 4, the target busy signal may be transferred to the power supply device 300. In this case, the host device 100 may in advance transmit information about the cut-off time point of the power being supplied to the storage device 2000 to the power supply device 300.

An SPOR test target, that is, whether to cut off the power of the storage device 2000 when any nonvolatile memory is operating during any target operation may be determined in advance depending on an SPOR test plan associated with the storage device 2000. Accordingly, the host device 100 may in advance transmit information about the cut-off time point of the power being supplied to the storage device 2000 to the power supply device 300. In this case, the information about the power cut-off time point may include information about one time point selected from a plurality of time points at which the target busy signal has the first voltage.

For example, based on that a current measured by the current measurement device 200 corresponds to a current profile associated with the target operation from among the plurality of current profiles, the host device 100 may transmit the information about the power cut-off time point to the power supply device 300.

According to the above description, the power supply device 300 may identify whether the power cut-off time point arrives, based on the received target busy signal and may cut off the power being supplied to the storage device 2000 at the identified power cut-off time point.

Comparing to two implementations described above, in terms of a reaction speed at which the power of the storage device 2000 is cut off after the power cut-off time point arrives, the implementation in which the target busy signal is transferred to the power supply device 300 may be more advantageous than the implementation in which the target busy signal is transferred to the host device 100.

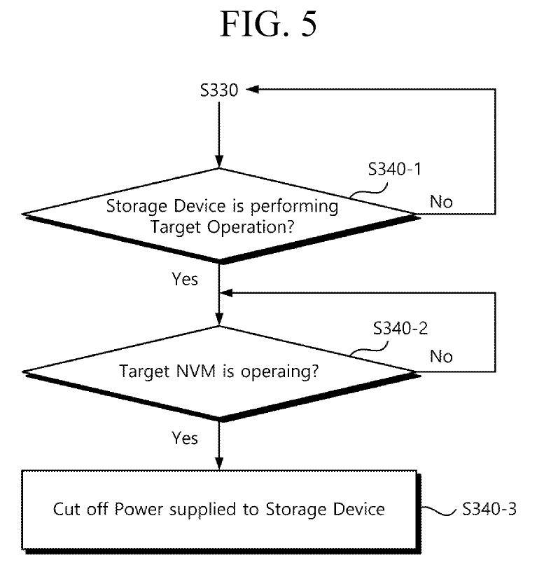

FIG. 5 is a flowchart for describing an operating method of a test system according to some implementations of the present disclosure. An operating method of a test system to be described with reference to FIG. 5 may correspond to operation S340 described with reference to FIG. 3.

Referring to FIG. 5, as described with reference to FIG. 3, in operation S330, the test system 1000 may identify whether the storage device 2000 is performing the target operation, based on the current measured by the current measurement device 200 and the plurality of current profiles.

When the identification result indicates that the storage device 2000 does not perform the target operation (No in operation S340-1), the test system 1000 may again perform operation S330.

In contrast, when the identification result indicates that the storage device 2000 is performing the target operation (Yes in operation S340-1), the test system 1000 may identify whether a target nonvolatile memory among the plurality of nonvolatile memories 2200 is operating.

In this case, whether the target nonvolatile memory is operating may be identified based on the busy signal (i.e., the target busy signal described above) of the target nonvolatile memory. To this end, the test system 1000 may transmit the selection signal for selecting a busy signal corresponding to the target nonvolatile memory from among the busy signals 20 of the plurality of nonvolatile memories 2200 to the storage device 2000, and the storage device 2000 may provide the target busy signal to the test system 1000 based on the selection signal.

When the target nonvolatile memory is operating is identified based on the target busy signal (Yes in operation S340-2), the test system 1000 may cut off the power of the storage device 2000 (S340-3). This is described in detail with reference to FIGS. 1 and 4, and thus, additional description will be omitted to avoid redundancy.

Meanwhile, according to some implementations, after the power being supplied to the storage device 2000 is cut off in operation S340-3, the host device 100 may control the power supply device 300 such that the power is again supplied to the storage device 2000. According to the above description, the host device 100 may check, from the storage device 2000, a result of the operation performed by the storage device 2000 when the power is cut off in operation S340-3.

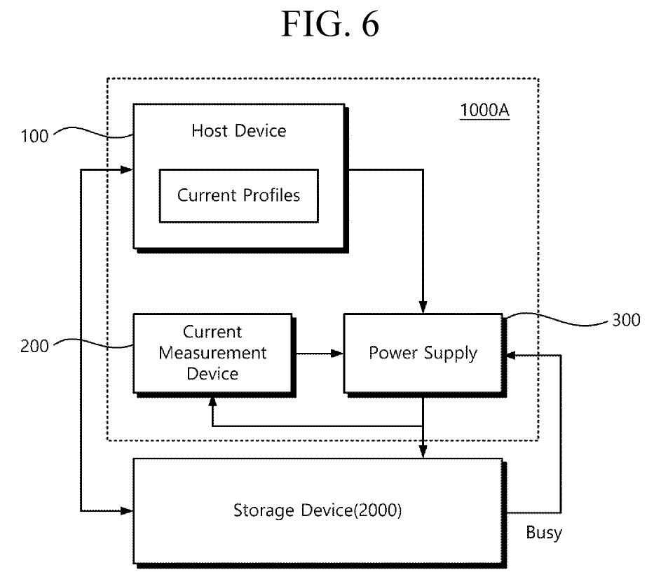

FIG. 6 is a block diagram of a test system according to some implementations of the present disclosure. Referring to FIG. 6, a test system 1000A may include the host device 100, the current measurement device 200, and the power supply device 300. The test system 1000A of FIG. 6 is the same as the test system 1000 of FIGS. 1 or 4 except that information about a current measured by the current measurement device 200 is provided to the power supply device 300. Accordingly, operations which are the same as the operations of the same components described above will not be described or will be simply described.

According to some implementations of the present disclosure, the power supply device 300 may identify whether the storage device 2000 is performing the target operation. To this end, the host device 100 may provide the plurality of current profiles to the power supply device 300. In this case, the power supply device 300 may store the plurality of current profiles. Also, the current measurement device 200 may provide the power supply device 300 with a current profile measured during the operation of the storage device 2000.

In this case, the power supply device 300 may identify whether the storage device 2000 is performing the target operation, based on the current profile received from the current measurement device 200 and the stored current profiles. In detail, when the current measured by the current measurement device 200 (or the current profile) corresponds to a current profile associated with the target operation from among the plurality of current profiles, the power supply device 300 may identify that the storage device 2000 is performing the target operation.

Meanwhile, the power supply device 300 may receive information about a power cut-off time point from the host device 100. Also, the power supply device 300 may receive the target busy signal from the storage device 2000. In this case, based on the information about the power cut-off time point and the target busy signal, the power supply device 300 may cut off the power of the storage device 2000 while the target nonvolatile memory is operating depending on the target operation.

For the above operation, according to some implementations, the power supply device 300 may include a micro-controller and a memory.

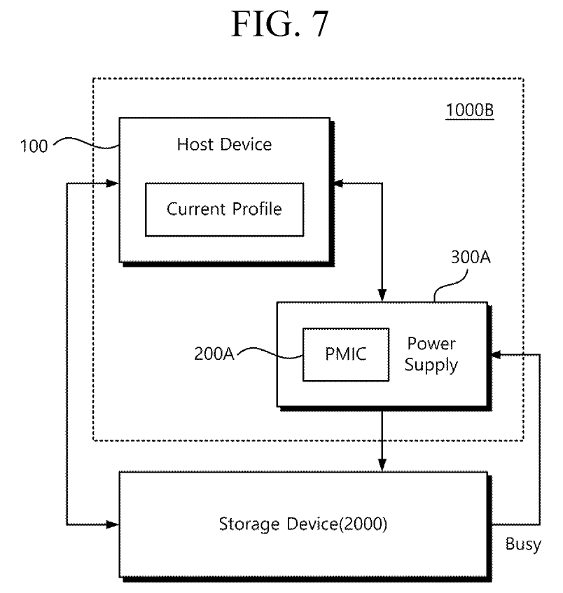

FIG. 7 is a block diagram of a test system according to some implementations of the present disclosure. A test system 1000B of FIG. 7 is the same as the test system 1000 or 1000A of FIGS. 1 and 4 or FIG. 6 except that the current measurement device 200 is not provided separately. Accordingly, operations which are the same as the operations of the same components described above will not be described or will be simply described.

According to some implementations of the present disclosure, the above function of the current measurement device 200 may be performed by a power management integrated circuit 200A included in a power supply device 300A.

Referring to FIG. 7, the test system 1000B may include the host device 100 and the power supply device 300A. In this case, the power supply device 300A may include the power management integrated circuit (PMIC) 200A. The power management integrated circuit 200A may manage a power which the power supply device 300A supplies to the storage device 2000.

The power which is provided to the storage device 2000 while the storage device 2000 is operating may correspond to a current consumed during the operation of the storage device 2000. Accordingly, the information (i.e., a current profile) associated with the current consumed by the storage device 2000 may be obtained through the power management integrated circuit 200A.

According to some implementations, the power supply device 300A may provide the host device 100 with the current profile obtained through the power management integrated circuit 200A. In this case, the host device 100 may identify whether the storage device 2000 is performing the target operation, based on the current profile received from the power supply device 300A and the stored current profiles.

Alternatively, according to some implementations, the power supply device 300A may receive and store the plurality of current profiles from the host device 100. In this case, the power supply device 300A may identify whether the storage device 2000 is performing the target operation, based on the current profile obtained through the power management integrated circuit and the stored current profiles.

Meanwhile, the power supply device 300A may receive information about a power cut-off time point from the host device 100 and may receive the target busy signal from the storage device 2000. In this case, based on the information about the power cut-off time point and the target busy signal, the power supply device 300A may cut off the power of the storage device 2000 while the target nonvolatile memory is operating depending on the target operation.

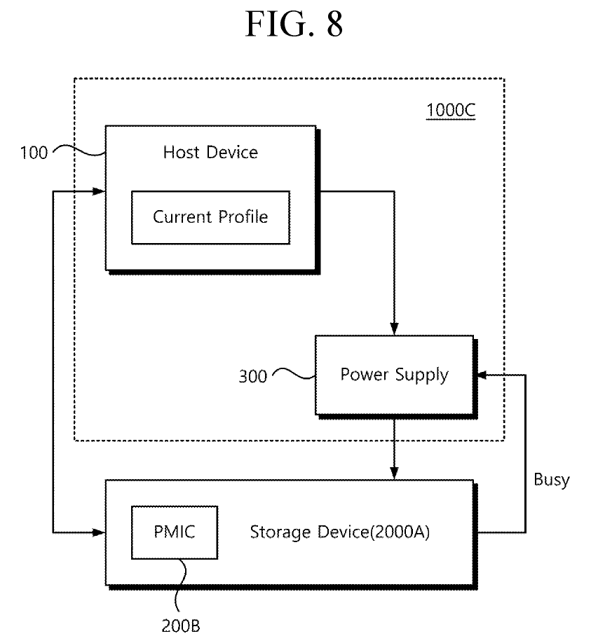

FIG. 8 is a block diagram of a test system according to some implementations of the present disclosure. A test system 1000C of FIG. 8 is the same as the test system 1000 or 1000A of FIGS. 1 and 4 or FIG. 6 except that the current measurement device 200 is not provided separately. Accordingly, operations which are the same as the operations of the same components described above will not be described or will be simply described.

According to some implementations of the present disclosure, the above function of the current measurement device 200 may be performed by a power management integrated circuit 200B included in a storage device 2000A.

Referring to FIG. 8, the test system 1000C may include the host device 100 and the power supply device 300. Also, the storage device 2000A may include the power management integrated circuit (PMIC) 200B. The power management integrated circuit 200B may manage a power which is used within the storage device 2000A.

The power which is consumed while the storage device 2000A is operating may correspond to a current consumed during the operation of the storage device 2000A. Accordingly, information (i.e., a current profile) associated with the current consumed by the storage device 2000A may be obtained through the power management integrated circuit 200B.

According to some implementations, the storage device 2000A may provide the host device 100 with the current profile obtained through the power management integrated circuit 200B. In some implementations, the current profile obtained through the power management integrated circuit 200B may be provided to the host device 100 through a side band interface between the storage device 2000A and the host device 100. In this case, the host device 100 may identify whether the storage device 2000A is performing the target operation, based on the current profile received from the storage device 2000A and the stored current profiles.

Meanwhile, the power supply device 300 may receive information about a power cut-off time point from the host device 100 and may receive the target busy signal from the storage device 2000A. Accordingly, based on the information about the power cut-off time point and the target busy signal, the power supply device 300 may cut off the power of the storage device 2000A while the target nonvolatile memory is operating depending on the target operation.

According to some implementations, when the target busy signal is provided to the host device 100, the host device 100 may identify whether the target nonvolatile memory is operating, based on the target busy signal. In this case, the host device 100 may apply, to the power supply device 300, the control signal for cutting off the power of the storage device 2000A while the target nonvolatile memory is operating depending on the target operation, and the power supply device 300 may cut off the power of the storage device 2000A based on the applied control signal.

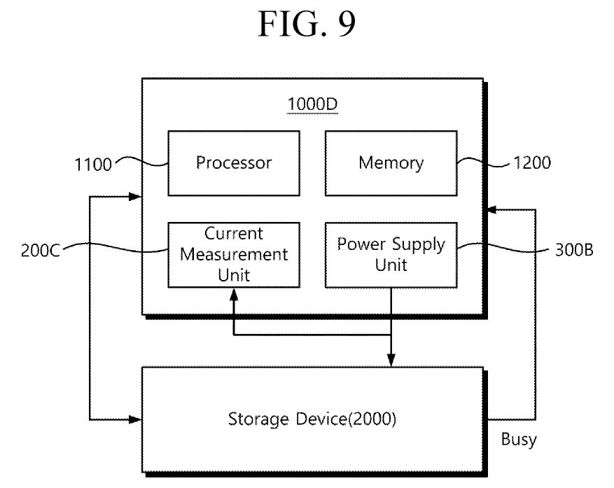

FIG. 9 is a block diagram of a test system according to some implementations of the present disclosure. According to some implementations of the present disclosure, the test system 1000 described above may be implemented with one SPOR test device. FIG. 9 shows a test system 1000D implemented with one device.

Referring to FIG. 9, the test system 1000D may include a processor 1100, a memory 1200, a current measurement unit 200C, and a power supply unit 300B.

The power supply unit 300B may correspond to the power supply device 300 described above. Accordingly, the power supply unit 300B may perform the function of the power supply device 300 described above. For example, under control of the processor 1100, the power supply unit 300B may supply the power to the storage device 2000 or may cut off the power being supplied to the storage device 2000. To this end, the power supply unit 300B may be connected to a power pin of the storage device 2000.

The current measurement unit 200C may correspond to the current measurement device 200 described above. Accordingly, the current measurement unit 200C may perform the function of the current measurement device 200 described above. For example, the current measurement unit 200C may measure a current which is consumed by the storage device 2000 while the storage device 2000 is operating. To this end, the current measurement unit 200C may be connected to the power pin of the storage device 2000.

The memory 1200 may store various kinds of programs and data for controlling the operation of the test system 1000D. Also, the memory 1200 may store a plurality of current profiles respectively corresponding to a plurality of operations of the storage device 2000. Herein, the plurality of operations of the storage device 2000 may include a plurality of test operations implemented through a combination of commands defined in the protocol specification such as non-volatile memory express (NVMe), universal flash storage (UFS), small computer system interface (SCSI), serial attached SCSI (SAS), or serial ATA (SATA).

The memory 1200 may include a volatile memory such as a static random access memory (SRAM), a dynamic RAM (DRAM), or a synchronous DRAM (SDRAM), and/or a nonvolatile memory such as a phase-change RAM (PRAM), a magneto-resistive RAM (MRAM), a resistive RAM (ReRAM), or a ferro-electric RAM (FRAM).

The processor 1100 may control all operations of the test system 1000D. The processor 1100 may include a central processing unit (CPU) or a micro-processor.

The processor 1100 may perform the above operation of the host device 100 based on the program and data stored in the memory 1200. For example, the processor 1100 may perform the SPOR test on the storage device 2000.

In detail, when the storage device 2000 is performing the target operation, the processor 1100 may control the power supply unit 300B to cut off the power being supplied to the storage device 2000. To this end, the processor 1100 may identify whether the storage device 2000 is performing the target operation, based on the current measured by the current measurement unit 200C and the plurality of current profiles stored in the memory 1200.

Also, while the target nonvolatile memory included in the storage device 2000 is operating depending on the target operation, the processor 1100 may control the power supply unit 300B to cut off the power being supplied to the storage device 2000. To this end, the processor 1100 may identify whether the target nonvolatile memory is operating, based on the target busy signal provided from the storage device 2000.

Meanwhile, the processor 1100 may transmit, to the storage device 2000, the selection signal for selecting the target busy signal among busy signals respectively output from the plurality of nonvolatile memories included in the storage device 2000. According to the above description, the storage device 2000 may provide the test system 1000D with the target busy signal among the busy signals respectively output from the plurality of nonvolatile memories.

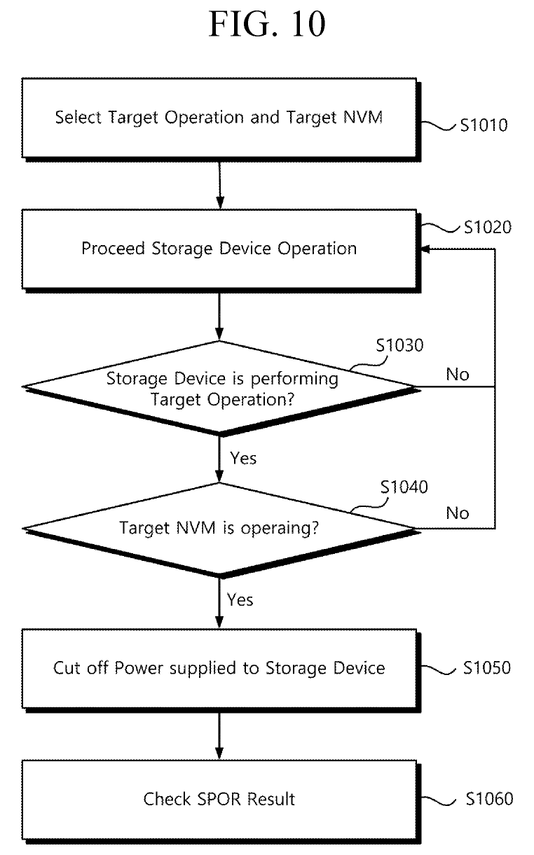

FIG. 10 is a flowchart for describing an operating method of a test system according to some implementations of the present disclosure.

Referring to FIG. 10, in operation S1010, the test system 1000, 1000A, 1000B, 1000C, or 1000D may determine the range of the SPOR test. For example, the host device 100 may determine a target operation and a target nonvolatile memory of the storage device 2000.

In operation S1020, the test system 1000, 1000A, 1000B, 1000C, or 1000D may allow the operation of the storage device 2000 to proceed. For example, the host device 100 may transmit commands and data to the storage device 2000 such that the storage device 2000 sequentially performs the plurality of operations depending on a predefined test scenario. In this case, the current measurement device 200 may measure a current consumed by the storage device 2000 and may provide a current profile to the host device 100 in real time.

In operation S1030, the test system 1000, 1000A, 1000B, 1000C, or 1000D may determine whether the storage device 2000 is performing the target operation. For example, when the current profile received from the current measurement device 200 is matched with a current profile corresponding to the target operation from among the plurality of current profiles stored in advance, the host device 100 may determine that the storage device 2000 is performing the target operation.

When it is determined that the storage device 2000 is performing the target operation, in operation S1040, the test system 1000 may determine whether the target nonvolatile memory is operating. In this case, whether the target nonvolatile memory is operating may be determined based on the target busy signal provided from the storage device 2000.

According to some implementations, the target busy signal may be provided to the host device 100. In this case, the host device 100 may determine whether the target nonvolatile memory is operating, based on the target busy signal. Alternatively, according to some implementations, the target busy signal may be provided to the power supply device 300. In this case, the power supply device 300 may determine whether the target nonvolatile memory is operating, based on the target busy signal.

When it is determined that the storage device 2000 is performing the target operation, in operation S1050, the test system 1000 may cut off the power being supplied to the storage device 2000.

According to some implementations, the host device 100 may apply, to the power supply device 300, the control signal for cutting off the power of the storage device 2000 at a power cut-off time point determined based on the target busy signal. The power supply device 300 may cut off the power of the storage device 2000 depending on the applied control signal.

Alternatively, according to some implementations, the host device 100 may provide information about the power cut-off time point to the power supply device 300. According to the above description, the power supply device 300 may cut off the power of the storage device 2000 based on the information about the power cut-off time point and the target busy signal.

Meanwhile, when it is determined in operation S1030 that the storage device 2000 does not perform the target operation or when it is determined in operation S1040 that the target nonvolatile memory does not operate, the test system 1000 may again perform operation S1020. In this case, the operation of the storage device 2000 may continuously proceed depending on the test scenario, and the current measurement device 200 may continuously provide the host device 100 with the current profile measured in real time.

In operation S1060, the test system 1000 may check a result of the SPOR operation which the storage device 2000 performs when the power is cut off. For example, in operation S1060, the host device 100 may control the power supply device 300 to again supply the power to the storage device 2000 and may check, from the storage device 2000, the result of the operation of the storage device 2000 performed when the power is cut off in operation S1050.

According to some implementations, the method according to various implementations of the present disclosure may be included and provided in a computer program product. The computer program product may be traded between a seller and a buyer as a commodity. The computer program product may be distributed online in the form of a machine-readable storage medium (e.g., a compact disk read only memory (CD-ROM)) or through an application store (e.g., Play Store^{TM}). In the case of the online distribution, at least part of the computer program product may be at least temporarily stored in a storage medium, such as a server of a manufacturer, a server of an application store, or a memory of a relay server or may be temporarily generated.

According to various implementations of the present disclosure described above, a test system capable of performing the SPOR test more efficiently may be provided.

According to implementations of the present disclosure, a test system capable of performing the SPOR test more efficiently may be provided.

As used herein, the term "at least one of" can refer to and encompass any and all possible combinations of one or more of the associated listed terms. For example, the term "at least one of A, B, or C" means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A test system comprising:
a power supply device configured to supply power to a storage device comprising a plurality of nonvolatile memories;
a current measurement device configured to measure current consumed by the storage device; and
a host device configured to control, based on the storage device performing a target operation, the power supply device to cut off the power,
wherein the host device is configured to
store a plurality of current profiles corresponding to a plurality of operations of the storage device, respectively, and
determine that the storage device is performing the target operation, based on (i) the current measured by the current measurement device and (ii) the plurality of current profiles.

2. The test system of claim 1, wherein the host device is configured to:
determine, based on the current measured by the current measurement device matching a first current profile associated with the target operation among the plurality of current profiles, that the storage device is performing the target operation.

3. The test system of claim 1, wherein each current profile of the plurality of current profiles comprises a waveform and/or a representative value of current consumed by the storage device during a corresponding operation.

4. The test system of claim 1, wherein the host device is configured to:
control, based on the target operation, the power supply device to cut off the power while a target nonvolatile memory of the plurality of nonvolatile memories is operating.

5. The test system of claim 4, wherein
determining that the storage device is performing the target operation comprises determining, based on a busy signal output from the target nonvolatile memory, that the target nonvolatile memory is operating, and
the busy signal comprises (i) a first voltage corresponding to a state in which the target nonvolatile memory is operating or (ii) a second voltage corresponding to a state in which an operation of the target nonvolatile memory is completed.

6. The test system of claim 5, wherein the host device is configured to:
transmit, to the storage device, a selection signal for selecting a busy signal output from the target nonvolatile memory, among a plurality of busy signals output from the plurality of nonvolatile memories.

7. The test system of claim 5, wherein the host device is configured to:
receive a busy signal output from the target nonvolatile memory; and
control, based on (i) the current measured by the current measurement device matching a current profile associated with the target operation among the plurality of current profiles and (ii) the received busy signal comprising the first voltage, the power supply device to cut off the power.

8. The test system of claim 5, wherein
the power supply device is configured to receive a busy signal output from the target nonvolatile memory,
the host device is configured to transmit, to the power supply device, information about a cut-off time of the power, based on the current measured through the current measurement device matching a current profile associated with the target operation among the plurality of current profiles, and
the power supply device is configured to:
determine an arrival of the cut-off time of the power, based on the received busy signal, and
cut off the power at the cut-off time.

9. The test system of claim 1, wherein
the plurality of operations of the storage device are test operations conducted through a combination of commands defined by a protocol used for communication between the host device and the storage device, and
the protocol comprises non-volatile memory express (NVMe), universal flash storage (UFS), small computer system interface (SCSI), serial attached SCSI (SAS), or serial ATA (SATA).

10. The test system of claim 1, wherein the host device is configured to:
control the storage device to perform each of the plurality of operations; and
obtain, based on the current measured by the current measurement device while the storage device is performing each of the plurality of operations, a current profile corresponding to each of the plurality of operations.

11. The test system of claim 4, wherein the host device is configured to:
control, based on the power being supplied to the storage device being cut off, the power supply device to supply the power to the storage device; and
determine a result of an operation of the storage device that is performed based on the power being cut off during the target operation.

12. The test system of claim 1, wherein
the power supply device comprises a power management integrated circuit (PMIC) configured to manage supply of power, and
the current measurement device is configured to operate based on using the power management integrated circuit of the power supply device.

13. The test system of claim 1 wherein the storage device comprises a power management integrated circuit (PMIC) configured to manage supply of power used within the storage device, and
wherein the current measurement device is configured to operate based on using the power management integrated circuit of the storage device.

14. A storage device comprising:
a plurality of nonvolatile memories, each nonvolatile memory of the plurality of nonvolatile memories being configured to output a busy signal;
a controller configured to control operations of the plurality of nonvolatile memories; and
a multiplexer connected to busy pins of the plurality of nonvolatile memories and configured to output a busy signal of a nonvolatile memory selected from the plurality of nonvolatile memories.

15. The storage device of claim 14, wherein the controller is configured to:
control, based on receiving a selection signal for selecting a target nonvolatile memory among the plurality of nonvolatile memories, the multiplexer to output a busy signal corresponding to the target nonvolatile memory, among busy signals of the plurality of nonvolatile memories.

16. The storage device of claim 14, comprising:
a power management integrated circuit configured to manage supply of power used within the storage device,
wherein the controller is configured to:
obtain information about current consumed during operation of the storage device, based on using the power management integrated circuit; and
transmit the obtained information of the current to an outside of the controller through a side band interface.

17. An operating method of a test system, the method comprising:
supplying power to a storage device comprising a plurality of nonvolatile memories;
measuring current consumed by the storage device;
determining, based on the current and a plurality of current profiles, that the storage device is performing a target operation; and
cutting off power being supplied to the storage device based on determining that the storage device is performing the target operation,
wherein the plurality of current profiles correspond to a plurality of operations of the storage device, respectively.

18. The method of claim 17, wherein cutting-off the power being supplied to the storage device comprises:
cutting off, based on the target operation, the power while a target nonvolatile memory among the plurality of nonvolatile memories is operating.

19. The method of claim 18, comprising determining that the target nonvolatile memory is operating based on a busy signal from the target nonvolatile memory,
wherein the busy signal of the target nonvolatile memory comprises (i) a first voltage corresponding to a state in which the target nonvolatile memory is operating or (ii) a second voltage corresponding to a state in which an operation of the target nonvolatile memory is completed.

20. The method of claim 19, comprising:
transmitting, to the storage device, a selection signal for selecting a busy signal corresponding to the target nonvolatile memory among a plurality of busy signals of the plurality of nonvolatile memories,
wherein the busy signal of the target nonvolatile memory is output from the storage device based on the selection signal.
